(19) United States
(12) Patent Application Publication
(10) Pub. No.: US 2004/0008495 A1
(43) Pub. Date: Jan. 15, 2004

(54) Printed circuit board assembly

(76) Inventor: Chin-Wei Ho, Taoyuan (TW)

Correspondence Address: BIRCH STEWART KOLASCH & BIRCH, PO BOX 747, FALLS CHURCH, VA, 22040-0747, US

(21) Appl. No.: 10/600,599

(22) Filed: Jun. 23, 2003

(30) Foreign Application Priority Data
Jun. 27, 2002 (TW) 091114185

(51) Int. Cl. H05K 1/00

(52) U.S. Cl. 361/748

(57) ABSTRACT

A printed circuit board assembly is disclosed. The printed circuit board assembly includes a first circuit board, a second circuit and a third circuit board. The first circuit board includes a first surface and a second surface opposite each other. The second circuit board is disposed on the first surface of the first circuit board and electrically connected thereto. The third circuit board is disposed on the second surface of the first circuit board and electrically connected thereto. The second and the third boards are both smaller than the first board. Electronic components with large thickness are mounted on the exposed first and second surfaces of the first circuit board. Electronic components with smaller thickness are mounted on the second or third circuit board.

### BACKGROUND OF THE INVENTION

1. Field of the Invention

The present invention relates in general to a printed circuit board. In particular, the present invention relates to a stepped circuit board, applicable in any electronic products.

2. Description of the Prior Art

Generally, conventional printed circuit boards are categorized into single-sided, double-sided, and multi-layer types. Electronic elements are placed on only one side of the single-sided board, resulting in strict limitations on layout. Thus, the layout must be carefully arranged so that the wires do not intersect, and additional jumper wires must also be installed. When using the double-sided circuit board, two sides must be electrically connected, with an electrical bridge between the two sides referred to as a via. The via is a through hole filled or painted with metal to electrically connect the wires on both sides. The usable area of the double-sided board is, obviously, twice as large as the area of the single-sided board, and the wires can be interconnected, thus, the double-sided board is mostly applicable for complicated circuits. To increase the area of layout, the multi-layer board was developed. It utilizes many single or double-sided layout layers and uses a number of double-sided boards with insulation layers therebetween, and is formed by pressing all layers together. The number of layers of a printed circuit board represents the number of independent layout layers, and is an even number. Multi-layer boards are connected using the same via technique, wherein the via must be arranged throughout the printed circuit layers to interconnect the wires on all layers. If only part of the layers need be connected, only the necessary layers are constructed with via. The area of layout can be increased simply by increasing the number of layers. In simple layout, the number of layers must be decreased so that the thickness of the circuit board is reduced and electronic element with height can be installed into the entire structure. For example, in the power supply zone, electronic elements are usually large, thus more space must be accommodated by the printed circuit boards.

According to the above technique, an improved design of a printed circuit board is needed. When layout is dense, the number of layers of the printed circuit board can be flexibly increased to connect wires. When layout is simple with large electronic elements, the number of layers can be decreased to provide space for element installation. Therefore, a flexible design of a printed circuit board is required.

FIG. 1A is a schematic diagram of a conventional printed circuit board assembly, including a conventional printed circuit board (102) and electronic elements (104), (106). The conventional printed circuit board is unable to provide decreased thickness flexibly. When installing a thinner electronic element (104), there is no space restriction. When installing a thicker electronic element (106), however, this is not the case. To complete layout, the area of the printed circuit board must be increased or the internal space of the entire electrical product must be increased, but some of the area of the printed circuit board is wasted and consequently cost is also increased. Moreover, the internal space cannot be fully utilized, and thus the volume of the electronic product cannot be reduced. FIG. 1B is an exploded diagram showing a cover and a conventional printed circuit board assembly, including a conventional multi-layer printed circuit board (102), electronic elements (104), (106), a cover (108), and protrusions (110) in the internal side of the cover (108). The thickness of the conventional printed circuit board (102) is uniform. When closing the cover (108), the electronic elements (104) cannot be placed beneath the protrusion (110) clearly shown in FIG. 1B. Thus the space under the protrusions (110) is wasted. Thicker electronic elements (106) also obstruct the cover during installation. Therefore, when there is a plurality of electronic elements and covers with protrusions, the electronic elements must be placed away from the obstruction limiting space for layout. It is thus necessary to increase the area of the printed circuit board (102). This wastes materials. To successfully install the electronic element (106), the height of cover (108) must be increased. As a result, the size of the electronic product cannot be reduced.

Moreover, during complicated layouts, the number of internal layers of the conventional printed circuit board cannot be selectively increased and connected. Thus, the total number of layers of the conventional printed circuit board must be increased together to complete complicated layout, but volume is thereby enlarged and materials are wasted.

### SUMMARY OF THE INVENTION

Therefore, an object of the invention is to provide a printed circuit board with adjustable internal layers to achieve variant thicknesses. According to the present invention, a board in the space limited by height of elements is thinner than the entire printed circuit board. Specifically, in zones where structures interfere with each other, the board has fewer layers than the board in other areas. For example, if a cavity is defined on the board to dispose an electronic element, and the relative elevation of the electronic element is lower, then the electronic element does not interfere with other structures.

Another object of the invention is to provide a printed circuit board on which elements with complicated pin arrays are accommodated by regionally increased numbers of internal layers to connect the wires. In other words, only in the regions where it is necessary to connect complicated pins of electronic elements, the number of internal layers can be appropriately increased. Thus, the number of layers of the printed circuit board in other areas does not vary with local electronic pin requirements.

Another object of the invention is to provide a flexible number of internal layers of a printed circuit board and effectively decrease the thickness thereof. Thus, space is allowed for installing electronic elements with height. The area of layout required becomes smaller, and this also saves material and associated costs. The number of internal layers of the present invention can be selectively increased when installing complicated electronic pins to separately connect layers by increasing the regional thickness.

Another object of the invention is to provide a printed circuit board with multiple layers so that the number of layers in at least one region is fewer than the number of the entire printed circuit board. Controlling the number of internal layers with variant thicknesses is to minimize the height of the space for installing electronic elements without interference.

Another object of the invention is to provide a printed circuit board with multiple layers such that, when closing a cover, regions where the electronic elements are installed include board layers fewer than the total board layers of the printed circuit board. The electronic elements do not interfere with the cover or the protrusions on the cover, allowing closure without relocating electronic elements. Thus, when the printed circuit board includes a plurality of electronic elements and a plurality of protrusions inside the cover, the area of the printed circuit board is minimized and the internal space of the product is maximized by controlling the number of the internal layers of printed circuit board to achieve different layer thickness.

A detailed description is given in the following embodiments with reference to the accompanying drawings.

### BRIEF DESCRIPTION OF THE DRAWINGS

The following detailed description, given by way of example and not intended to limit the invention solely to the embodiments described herein, will best be understood in conjunction with the accompanying drawings, in which:

FIG. 1A (Prior Art) is a schematic diagram showing a conventional printed circuit board assembly;

FIG. 1B (Prior Art) is a schematic diagram showing a cover on the conventional printed circuit board assembly of FIG. 1A;

FIG. 2A is a schematic diagram showing a printed circuit board assembly of the first embodiment in the present invention;

FIG. 2B is a cross-section of FIG. 2A along line A-A for the first embodiment of the present invention;

FIG. 3 is a schematic diagram showing a printed circuit board assembly and a cover of the second embodiment of the present invention; and

FIG. 4 is an exploded diagram showing a printed circuit board assembly and a cover of the third embodiment of the present invention.

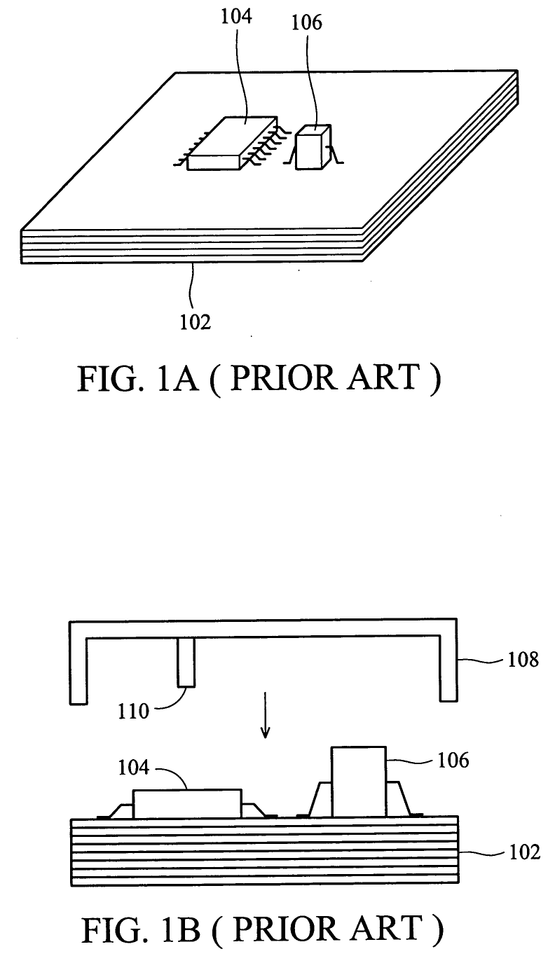

### DETAILED DESCRIPTION OF THE INVENTION

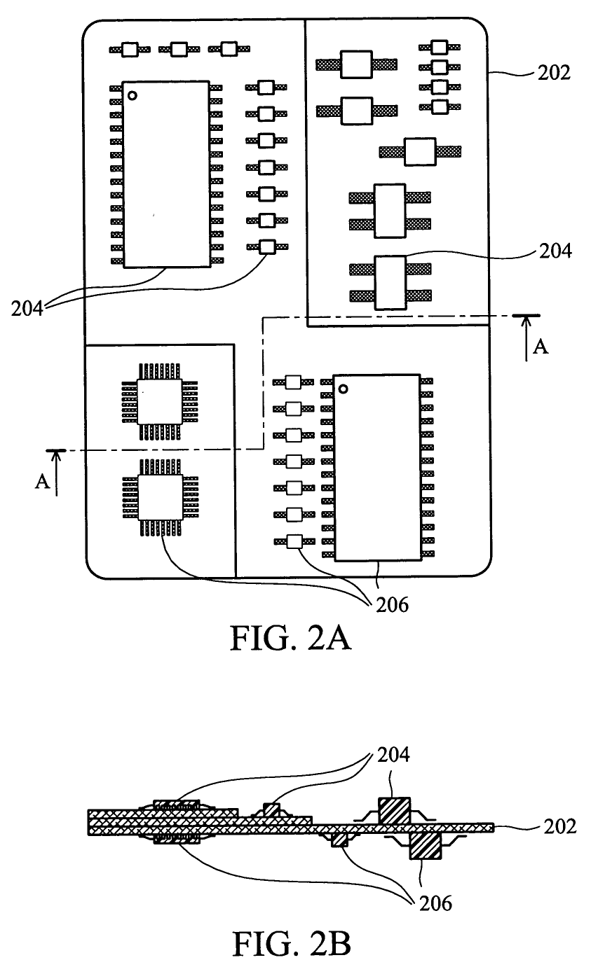

FIGS. 2A and 2B show a printed circuit board assembly of the present invention. FIG. 2A shows a printed circuit board assembly of the first embodiment including a multi-layer printed circuit board (202) and electronic elements (204), (206). The multi-layer printed circuit board (202) provides at least one region where the number of board layers is fewer than the total number of layers of the entire multi-layer printed circuit board (202). The number of internal board layers of the printed circuit board is controlled to create different board thicknesses. Thus, the electronic elements (204) and (206) with different heights do not interfere with other structures.

FIG. 2B is a cross-sectional view taken along line A-A of FIG. 2A. As shown in FIG. 2B, the multi-layer printed circuit board (202) includes three boards, where large, medium, and small boards are stacked together in stepped form. The number of layers is changeable and varies with respect to different regions. Some regions have thinner boards where larger or higher elements can be disposed, and some regions have thicker boards and many layers for placing smaller elements. Thus, a multi-layer printed circuit board (202) has some regions with lower height than the entire multi-layer printed circuit board (202). In other words, some regions have fewer layers than the total number of layers of the multi-layer printed circuit board (202).

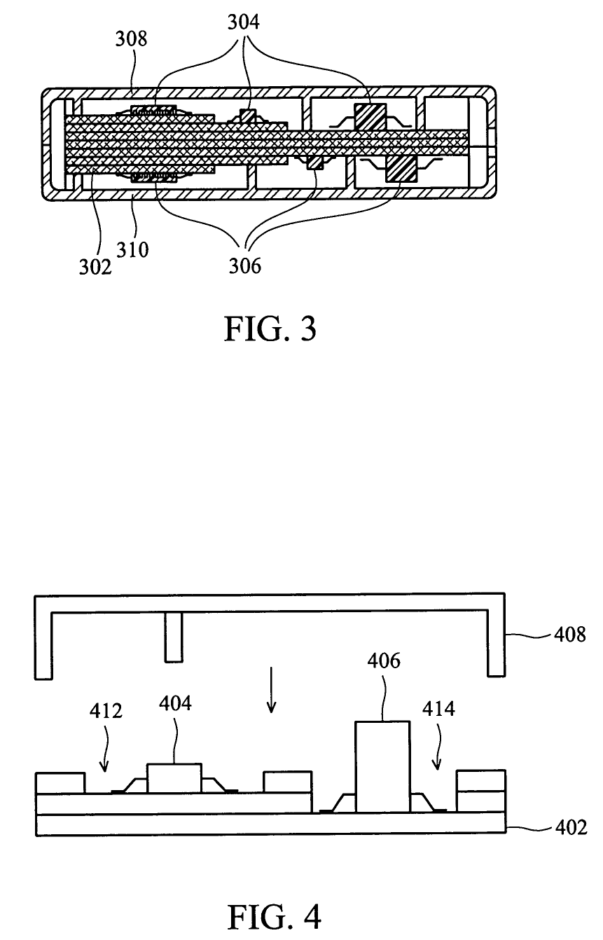

FIG. 3 is a schematic diagram showing a printed circuit board assembly and a cover of the second embodiment of the present invention. FIG. 3 illustrates a multi-layer printed circuit board (302), electronic elements (304) and (306), an upper cover (308) and a lower cover (310). As shown in FIG. 3, the multi-layer circuit board (302) is composed of seven boards with different sizes: large, medium and small, stacked together. The boards are stacked symmetrically.

When closing the upper cover (308) and the lower cover (310), the electronic elements (304) and (306) do not interfere with the covers (308) and (310) because the printed circuit board includes a region with fewer layers and other regions with more layers and there is enough room for installing the elements. The usable area of the printed circuit board (302) is maximized and material wasted is minimized. Thus the size of the electronic product is greatly reduced. Moreover, the boards can also be stacked asymmetrically according to the demand of installation. The thickness of the board and the number of layers can be arranged arbitrarily.

FIG. 4 is an exploded diagram showing a printed circuit board assembly and a cover of the third embodiment of the present invention. According to the FIG. 4, the multi-layer printed circuit board (402) is stacked with a plurality of boards having the same thickness. The boards are electrically interconnected. Electronic elements (404) (406), an upper cover (408), and cavities (412) (414) are shown in the figure. In the third embodiment, the electronic elements (404) (406) do not interfere with the upper cover (408) when closing. The reason is that the higher element (406) is located in the deeper cavity (414) and mounted on the circuit board (402), and the other element (404), which has a less thickness is located in the shallow cavity (412) and mounted on the circuit board over the circuit board (402). Thus, the electronic elements are disposed at different levels to avoid causing interference with the cover when assembling the cover and the circuit board assembly together.

Therefore, as mentioned above, the advantage of the present invention is that the thickness of boards is effectively decreased, such that available room for element installation is greatly increased with a minimum area of printed circuit board. Consequently, the cost for the materials of printed circuit board is reduced.

Furthermore, the number of internal layers can be increased regionally when the product must accommodate complicated pins on electronic elements, thus layers in such regions are increased for connecting the elements without increasing the entire thickness of the printed circuit board.

Finally, while the invention has been described by way of example and in terms of the preferred embodiments, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A printed circuit board assembly, including:
a first board containing a first circuit; and
a second board smaller than the first board and disposed on the first board, wherein the second board contains a second circuit electrically connected to the first circuit.

2. A printed circuit board as claimed in claim 1, wherein the second board defines at least one cavity with the first board.

3. A printed circuit board assembly, including:
a first circuit board including a first surface and a second surface opposite each other;
a second circuit board smaller than the first circuit board, disposed on the first surface of the first circuit board and electrically connected to the first circuit board; and
a third circuit board smaller than the first circuit board, disposed on the second surface of the first circuit board and electrically connected to the first circuit board.

4. A printed circuit board as claimed in claim 3, wherein the second circuit board is as large as the third circuit board.

5. A printed circuit board as claimed in claim 3, wherein the second circuit board defines at least one cavity with the first circuit board.

6. A printed circuit board as claimed in claim 3, wherein the third circuit board defines at least one cavity with the first circuit board.

7. An electrical combination comprising:
a multi-layer printed circuit board having different regions with different heights; and
a plurality of electronic components mounted on the printed circuit board, wherein the electronic components have different thickness, wherein the electronic component with the more thickness is mounted on the region of the printed circuit board with the less height.

8. The electrical combination as claimed in claim 7 further comprising a cover covering the printed circuit board and the electronic components without interference with the electronic components.

9. The electrical combination as claimed in claim 8, wherein the cover comprises at least a protrusion extending toward the printed circuit board.

10. The electrical combination as claimed in claim 9, wherein the electronic component with the less thickness is located below the at least one protrusion.

11. The electrical combination as claimed in claim 7, wherein the different regions of the printed circuit board with different heights are arranged in a stepped form.
